(19) United States
(12) Patent Application Publication
(10) Pub. No.: US 2026/0361982 A1
(43) Pub. Date: Nov. 12, 2026

(54) IMAGE PICKUP APPARATUS CAPABLE OF IMPROVING GRIP CAPABILITY OF THE IMAGE PICKUP APPARATUS WHILE SUPPRESSING TEMPERATURE RISE INSIDE THE IMAGE PICKUP APPARATUS

(71) Applicant: CANON KABUSHIKI KAISHA, Tokyo (JP)

(72) Inventor: HAYATO MANO, Tokyo (JP)

(21) Appl. No.: 19/660,506

(22) Filed: Apr. 28, 2026

(30) Foreign Application Priority Data
May 12, 2025 (JP) 2025-079892

(51) Int. Cl. H04N 23/52; H04N 23/51; H05K 7/20

(52) U.S. Cl. CPC H04N 23/52; H04N 23/51; H05K 7/20172

(57) ABSTRACT

An image pickup apparatus capable of improving the grip capability of the image pickup apparatus while suppressing a temperature rise inside the image pickup apparatus is provided. The image pickup apparatus includes a lens barrel, a gripping portion for gripping a case of the image pickup apparatus, a substrate on which a heat generating element is mounted, disposed on a side face of the lens barrel, and a heat dissipation device configured to be disposed on the side face, have a flow path connecting an intake port provided in the case to an exhaust port provided in the case, and be thermally connected to the heat generating element. The heat dissipation device and the gripping portion do not overlap with each other when viewed from a perpendicular direction of the gripping portion.

### BACKGROUND

### Field of the Technology

The present disclosure relates to an image pickup apparatus.

### Description of the Related Art

In an image pickup apparatus, there is a need for a structure with a higher heat dissipation effect (a higher heat dissipation capacity) to cope with the increased heat generation resulting from the increased power consumption caused by the recent increase in the pixel count of an image pickup device (an image sensor), etc. For example, a structure has been proposed in which the inside of an image pickup apparatus is cooled by using a blower fan and a duct (see Japanese Patent No. 6882093).

However, with the structure disclosed in Japanese Patent No. 6882093, since the blower fan and the duct are provided to cool the inside of the image pickup apparatus, the weight of the image pickup apparatus increases, and the image pickup apparatus also becomes larger. In addition, since the blower fan and the duct are disposed on a side portion of a lens barrel between the lens barrel and a gripping portion, a distance between the gripping portion and the lens barrel that is a heavy object increases when a user grips the image pickup apparatus. There has been an issue that as the centroid of the image pickup apparatus and the gripping position become separated, the load on the user's hand increases, and the grip capability decreases.

### SUMMARY

The present disclosure provides an image pickup apparatus capable of improving the grip capability of the image pickup apparatus while suppressing a temperature rise inside the image pickup apparatus.

Accordingly, an aspect of the present disclosure provides an image pickup apparatus comprising a lens barrel, a gripping portion for gripping a case of the image pickup apparatus, a substrate on which a heat generating element is mounted, disposed on a side face of the lens barrel, and a heat dissipation device configured to be disposed on the side face, have a flow path connecting an intake port provided in the case to an exhaust port provided in the case, and be thermally connected to the heat generating element. The heat dissipation device and the gripping portion do not overlap with each other when viewed from a perpendicular direction of the gripping portion.

Features of the present disclosure will become apparent from the following description of embodiments with reference to the attached drawings. The following description of embodiments is described by way of example.

### BRIEF DESCRIPTION OF THE DRAWINGS

FIGS. 1A and 1B are a front perspective view and a rear perspective view of an image pickup apparatus according to one embodiment of the present disclosure.

FIGS. 2A and 2B are a front perspective view and a rear perspective view, respectively, illustrating a state where a user is gripping the image pickup apparatus.

FIGS. 3A, 3B, and 3C are a front perspective view, a rear perspective view, and a sectional view taken along line A-A of a heat dissipation device.

FIGS. 4A and 4B are a front perspective view and a side view, respectively, illustrating an internal structure of the image pickup apparatus.

FIG. 5 is an exploded perspective view illustrating the internal structure of the image pickup apparatus.

FIGS. 6A and 6B are a side view and a sectional view taken along line C-C of the image pickup apparatus.

### DESCRIPTION OF THE EMBODIMENTS

The present disclosure will now be described in detail below with reference to the accompanying drawings showing embodiments thereof.

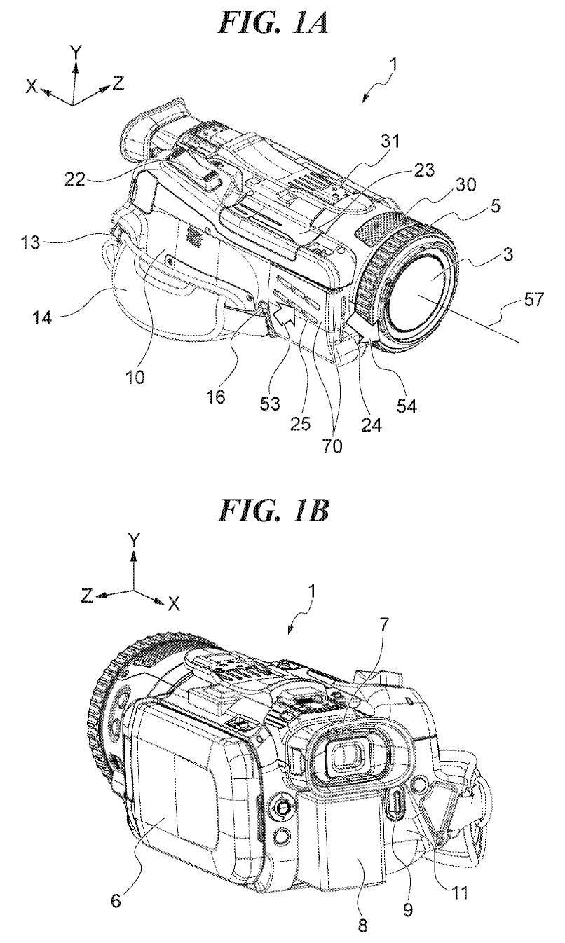

FIGS. 1A and 1B are a front perspective view and a rear perspective view, respectively, of an image pickup apparatus 1 according to one embodiment of the present disclosure. The image pickup apparatus 1 is, for example, a video camera.

Hereafter, the direction of each part will be referred to, based on X, Y, and Z coordinate axes that are shown in FIGS. 1A, 1B, etc. For convenience, in the present disclosure, in a direction parallel to a photographing optical axis 57, a subject side is defined as the front, and a photographer side (a user side) is defined as the rear. The X-axis direction is parallel to the optical axis direction shown in FIG. 1A, and the subject side is defined as the -X side. In a direction perpendicular to the X-axis, the width direction of the image pickup apparatus 1 is defined as the Z-axis direction, and the right side as viewed from the subject side is defined as the +Z side. In addition, the top-and-bottom direction of the image pickup apparatus 1 is defined as the Y-axis direction, and the upper side is defined as the +Y side.

A lens unit 3 is disposed at a front portion of the image pickup apparatus 1, and an operating ring 5, which allows for manual focus and other operations, is provided on an outer circumference portion of the lens unit 3. A display unit 6, which is configured by a liquid crystal display (an LCD) or the like, is provided on the +Z side in the image pickup apparatus 1, so that the display unit 6 is capable of being opened and closed. A viewfinder 7, a battery 8, a recording button 9 are disposed at a rear portion of the image pickup apparatus 1.

A first grip portion 10 (a gripping portion) for a user to grip a case 70 of the image pickup apparatus 1 is provided on the -Z side in the image pickup apparatus 1. A second grip portion 11 is provided below the recording button 9 disposed at the rear portion of the image pickup apparatus 1. A first grip belt holder 13 is provided on the +X side of the first grip portion 10, and a second grip belt holder 16 is provided on the -X side of the first grip portion 10. A grip belt 14, which is fixed to the first grip belt holder 13 and the second grip belt holder 16, is a belt member for the user to grip the image pickup apparatus 1. The first grip portion 10 is disposed between the first grip belt holder 13 and the second grip belt holder 16, which are two mounting portions for attaching (mounting) the grip belt 14, in the optical axis direction.

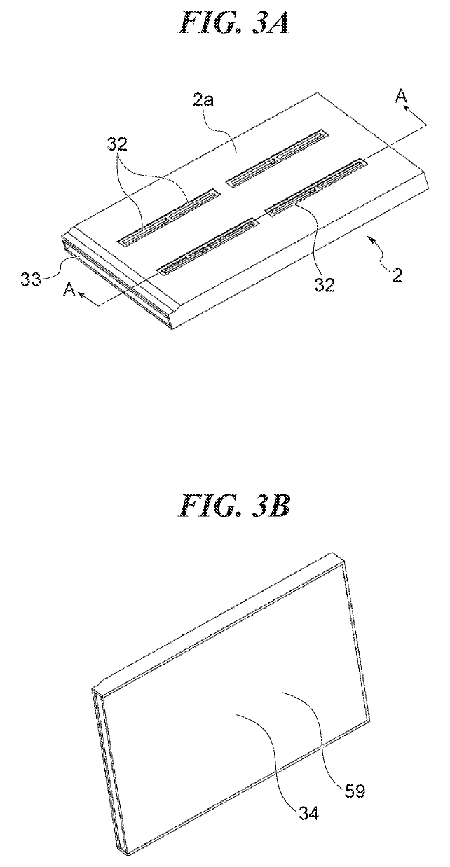

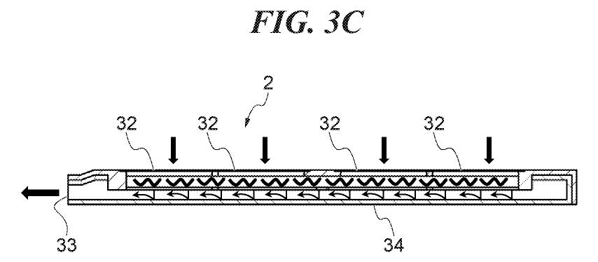

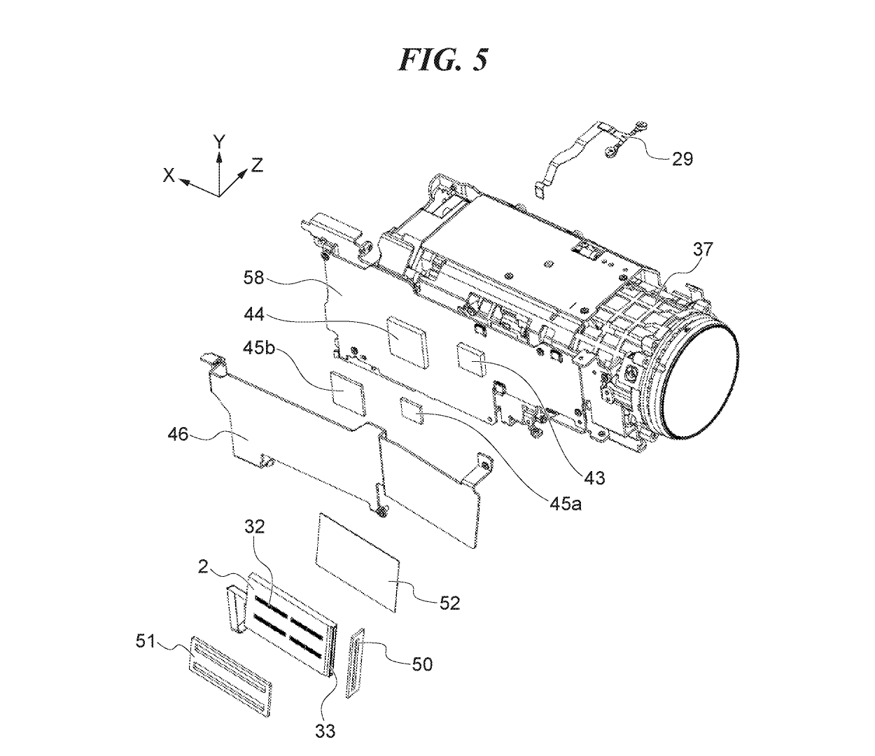

A top portion of the image pickup apparatus 1 is equipped with a rocker zoom 22 and an openable/closable card lid 23. A recording medium (not shown) such as an SD card is inserted inside the card lid 23. In addition, starting from the subject side, a microphone hole 30, which communicates with a microphone 29 (see FIG. 5), and an accessory fixing portion 31, to which an external accessory is capable of being attached, are disposed. The image pickup apparatus 1 is equipped with a heat dissipation device 2 (see FIG. 3A), which will be described below. The heat dissipation device 2 is a device that takes in ambient air, and exhausts it to the outside along with the heat generated inside the image pickup apparatus 1.

Two exhaust ports 24 are disposed at the front portion of the image pickup apparatus 1. All of the exhaust ports 24 are disposed closer to the subject side than the first grip portion 10 in the optical axis direction, facing the subject side and opening downward from the optical axis 57. On a side portion on the -Z side of the image pickup apparatus 1, six intake ports 25 are provided on the -X side of the second grip belt holder 16. All of the intake ports 25 are open facing the -Z side. The exhaust ports 24 and the intake ports 25 are formed in the case 70 of the image pickup apparatus 1.

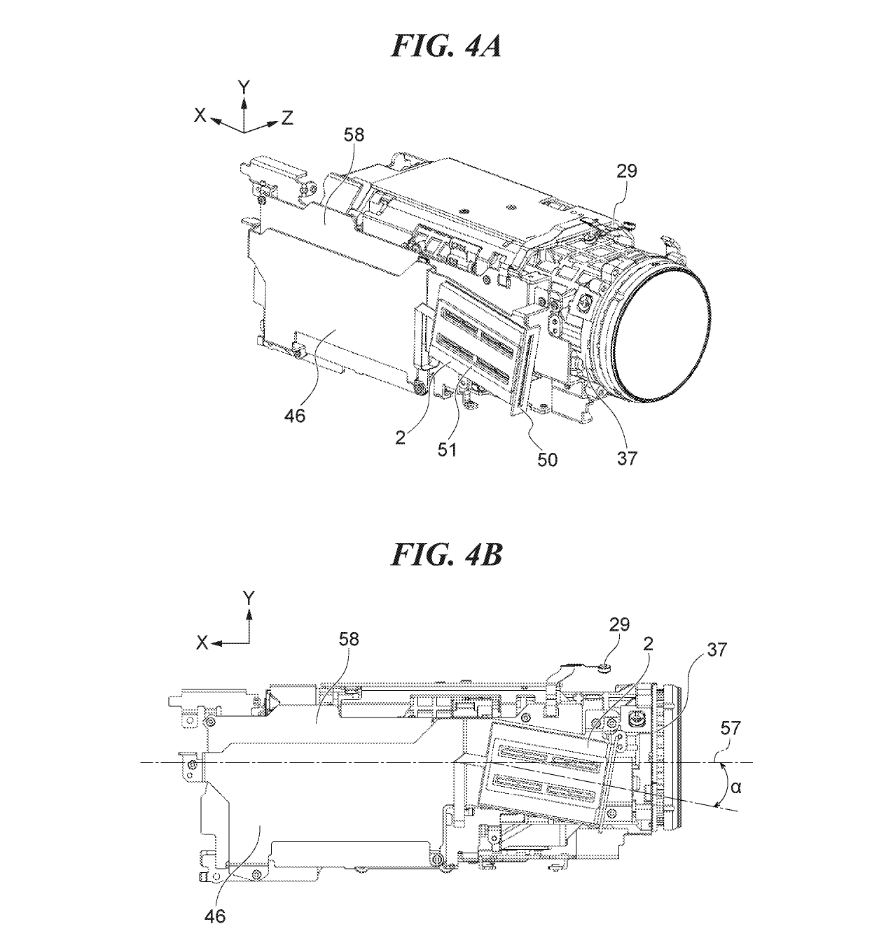

An arrow 53 shown in FIG. 1A indicates an intake airflow to the intake ports 25, and an arrow 54 shown in FIG. 1A indicates an exhaust airflow from the exhaust ports 24. The exhaust ports 24 are open facing the subject side and facing downwards, which has the effect of making it less likely for the microphone 29 inside the microphone hole 30 to pick up a noise from the heat dissipation device 2, and also has the effect of making it less likely for wind to directly hit the subject (as will be described below also with reference to FIG. 4B).

It should be noted that since the grip belt 14 and the battery 8 are capable of being attached (mounted) later, the grip belt 14 and the battery 8 may not be included in the components of the image pickup apparatus 1.

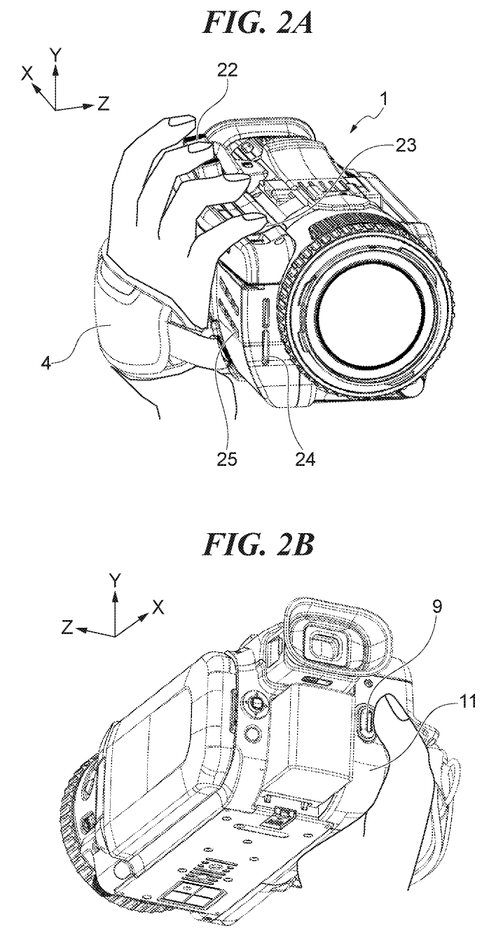

FIGS. 2A and 2B are a front perspective view and a rear perspective view, respectively, illustrating a state where the user is gripping the image pickup apparatus 1.

As shown in FIGS. 2A and 2B, the user places the little finger, the ring finger, the middle finger, and the index finger of his/her right hand between the grip belt 14 and the first grip portion 10 (see FIG. 1A), places his/her right palm against the first grip portion 10, and places the back of his/her right hand against the grip belt 14. The user, if necessary, places the little finger and the ring finger on the card lid 23 and rests the base of his/her thumb against the second grip portion 11. In this state, the user operates the rocker zoom 22 with the index finger and the middle finger, and operates the recording button 9 with his/her thumb.

As will be described below, since the intake ports 25 are disposed in front of the front end of the first grip portion 10, the user does not block the intake ports 25 with his/her hand when gripping the image pickup apparatus 1.

FIGS. 3A and 3B are a front perspective view and a rear perspective view, respectively, of the heat dissipation device 2. FIG. 3C is a sectional view taken along line A-A shown in FIG. 3A.

The heat dissipation device 2 includes a back face 59 (an opposing face) and a main face 2a opposite to the back face 59. The back face 59 is a face facing a main circuit board 58 (a main circuit substrate 58) (see FIF. 5) in the Z-axis direction, and is parallel to the main face 2a.

The main face 2a is provided with a plurality of air intake ports 32 for drawing in outside air. The heat dissipation device 2 is equipped with an air exhaust port 33. The air exhaust port 33 opens in a direction substantially perpendicular to the back face 59 and the main face 2a. The back face 59 is configured by a heat diffusion plate 34 (a heat diffusion portion) that is made of a member (a material) with high thermal conductivity, such as copper or aluminum. The heat dissipation device 2 has a flow path that connects the intake ports 25 to the exhaust ports 24 (see FIG. 1A). The heat diffusion plate 34 constitutes a part of the flow path, which is from the air intake ports 32 to the air exhaust port 33.

Arrows shown in FIG. 3C indicate the flow of the air, and wavy lines shown in FIG. 3C indicate a thin film enclosed within the heat dissipation device 2. This thin film vibrates at high speed, causing the heat dissipation device 2 to draw in the air from the air intake ports 32. The air drawn in absorbs heat from the heat diffusion plate 34, and then is discharged from the air exhaust port 33 of the heat dissipation device 2. In this way, the heat dissipation device 2 is capable of cooling heat dissipation target component(s).

Next, the heat dissipation structure of the image pickup apparatus 1 will be described with reference to FIGS. 4A-6B.

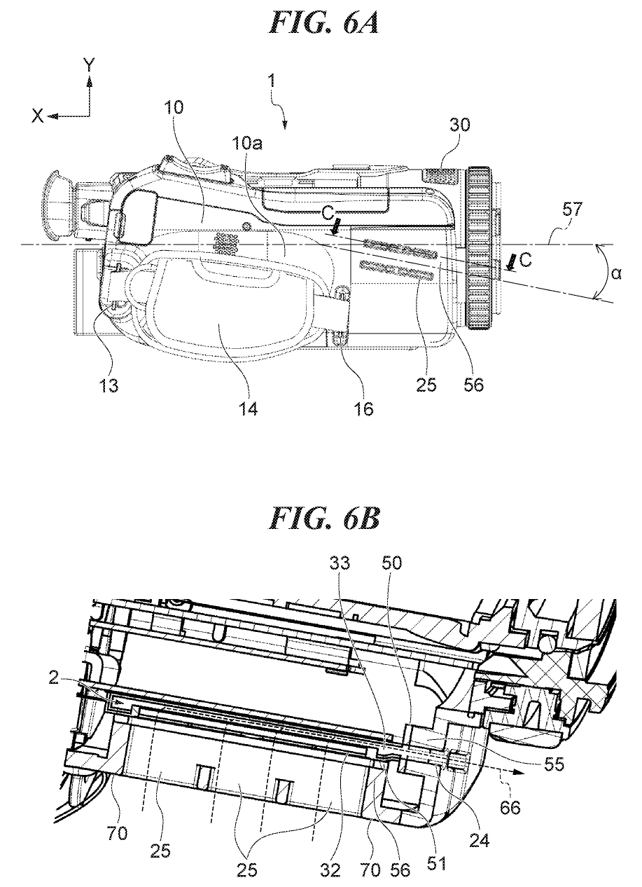

FIGS. 4A and 4B are a front perspective view and a side view, respectively, illustrating an internal structure of the image pickup apparatus 1. FIG. 5 is an exploded perspective view illustrating the internal structure of the image pickup apparatus 1. FIG. 6A is a side view of the image pickup apparatus 1. FIG. 6B is a sectional view taken along line C-C shown in FIG. 6A.

A first IC chip 43 shown in FIG. 5 is responsible for processing data from an image pickup device (an image sensor) (not shown) and outputting it as a video image. Specifically, the first IC chip 43 performs image compression, noise reduction, color correction, and frame rate adjustment. The first IC chip 43 generates heat when performing signal processing. When the first IC chip 43 is at a high temperature (becomes hot), this leads to an increase in noise, a decrease in the quality of the video image, a slower processing speed, and accelerated component degradation. Therefore, a measure has been taken to cool the first IC chip 43. In addition, the image pickup apparatus 1 is equipped with a second IC chip 44. The second IC chip 44 is, for example, a power supply circuit and a field programmable gate array (an FPGA), and similar to the first IC chip 43, it is necessary to cool the second IC chip 44.

Most of a lens barrel 37 is covered by the case 70 (see FIG. 1A). The main circuit board 58 is disposed on a side face on the -Z side of the lens barrel 37. The first IC chip 43 and the second IC chip 44 are mounted on the main circuit board 58, and a heat dissipation rubber 45a and a heat dissipation rubber 45b (hereinafter, the heat dissipation rubber 45a or the heat dissipation rubber 45b is simply referred to as a heat dissipation rubber 45), which are heat conductive rubber, are attached (sticked) to the first IC chip 43 and the second IC chip 44 (heat generating elements), respectively. A face on the -Z side of the heat dissipation rubber 45 is in contact with a metal plate 46 that has high thermal conductivity, such as a copper plate or an aluminum plate. The main circuit board 58 is equipped with a controller such as a central processing unit (a CPU) that controls the second IC chip 44 and the first IC chip 43.

The heat dissipation device 2 is fixed to a face on the -Z side of the metal plate 46 by using a double-sided tape 52 with high thermal conductivity. With this configuration, the heat generated by the first IC chip 43 and the second IC chip 44, which are the heat generating elements, is transferred to the heat diffusion plate 34 (see FIGS. 3B and 3C of the heat dissipation device 2 via the heat dissipation rubber 45, the metal plate 46, and the double-sided tape 52.

In this way, the heat diffusion plate 34 of the heat dissipation device 2, which is disposed on the side face on the -Z side of the lens barrel 37, is thermally connected to the second IC chip 44 and the first IC chip 43. It should be noted that as a heat transfer member used to thermally connect the second IC chip 44 and the first IC chip 43 to the heat dissipation device 2, a gap filler, a graphite sheet, a heat conductive adhesive, a heat conductive grease, a heat pipe, or the like may be adopted.

The air intake ports 32 of the heat dissipation device 2 are in communication with the intake ports 25 of the case 70 (see FIGS. 1A and 2A). In addition, the air exhaust port 33 of the heat dissipation device 2 is in communication with the exhaust ports 24 of the case 70 (see FIGS. 1A and 2A).

An arrow 66 shown in FIG. 6B indicates the flow of the air being drawn in and exhausted by the image pickup apparatus 1. The air drawn into the image pickup apparatus 1 through the intake ports 25 is taken into the heat dissipation device 2 from the air intake ports 32, and then is discharged outside the image pickup apparatus 1 through the air exhaust port 33 and the exhaust ports 24 along with the heat from the heat diffusion plate 34.

The heat dissipation device 2 is disposed on the -Z side of the image pickup apparatus 1, which is the side, on which the first grip portion 10 is disposed. The heat dissipation device 2 is disposed substantially parallel to the main circuit board 58. The heat dissipation device 2 is located closer to the -X side than the first grip portion 10, and is not located between the lens barrel 37 and the first grip portion 10 in the Z-axis direction.

As a result, the heat dissipation device 2 and the first grip portion 10 do not overlap with each other when viewed from a perpendicular direction of the first grip portion 10 (a direction perpendicular to the face of the first grip portion 10) (a normal direction of a side face 10a on the -Z side). Here, the perpendicular direction of the first grip portion 10 is parallel to the Z-axis direction and the side face on the -Z side of the lens barrel 37. The side face 10a is a gripping face of the first grip portion 10.

Such an arrangement allows the distance between the lens barrel 37 and the first grip portion 10 to be reduced in the Z-axis direction, thereby reducing the load on the user's hand when gripping the image pickup apparatus 1 and improving the grip capability.

In addition, since the intake ports 25 are located closer to the -X side than the first grip portion 10 (see FIG. 6A), the intake ports 25 are not blocked when the user grips the image pickup apparatus 1, ensuring high cooling performance.

As shown in FIGS. 4A, 5, and 6B, a soft elastic member 50 is disposed on the -X side of the heat dissipation device 2, and a soft elastic member 51 is disposed on the -Z side of the heat dissipation device 2. The elastic member 50 is attached to an exterior portion 55 (see FIG. 6B) of the case 70 so as not to block the communicating portion between the exhaust ports 24 of the case 70 and the air exhaust port 33. As a result, the elastic member 50 fills a gap between the area around the air exhaust port 33 and the exterior portion 55 (see FIG. 6B).

The elastic member 51 is attached to the main face 2a of the heat dissipation device 2 so as not to block the communicating portion between the intake ports 25 of the case 70 and the air intake ports 32. As a result, the elastic member 51 fills a gap between the area around the air intake ports 32 and an exterior portion 56 (see FIG. 6B) of the case 70.

The presence of the elastic member 50 and the elastic member 51 (due to the elastic member 50 and the elastic member 51 being provided) prevents water and dust from entering the image pickup apparatus 1. In addition, since the heat dissipation device 2 and the case 70 are connected via the elastic member 50 and the elastic member 51, the vibration from the heat dissipation device 2 is less likely to be transmitted to the user via the exterior portion 55 and the exterior portion 56. Furthermore, in the case where the image pickup apparatus 1 has fallen, the impact will not be directly transmitted to the heat dissipation device 2, thus suppressing the failure of the heat dissipation device 2.

As shown in FIGS. 4A and 4B, the microphone 29 is disposed on a top face (a top portion) of the lens barrel 37. The top face of the lens barrel 37 is a face different from the side face on the -Z side of the lens barrel 37. The heat dissipation device 2 is disposed so that its front portion is tilted at an angle α in a direction away from the microphone 29 with respect to the optical axis 57 (see FIGS. 4B and 6A). As a result, the microphone 29 becomes less likely to pick up the noise emitted by the heat dissipation device 2.

According to the present embodiment, since the heat dissipation device 2 has the flow path that connects the intake ports 25 to the exhaust ports 24 and is thermally connected to the second IC chip 44, the cooling performance of the second IC chip 44 is ensured. In addition, since the heat dissipation device 2 and the first grip portion 10 do not overlap with each other when viewed from the Z-axis direction, the grip capability is good. Therefore, it is possible to improve the grip capability of the image pickup apparatus while suppressing a temperature rise inside the image pickup apparatus.

In the present embodiment, although the heat dissipation device 2 and the intake ports 25 are disposed closer to the -X side than the first grip portion 10, in a larger image pickup apparatus model, even in the case where the heat dissipation device 2 and the intake ports 25 are disposed closer to the +X side than the first grip belt holder 13, it is possible to obtain the same effects.

In addition, although the main circuit board 58 and the heat dissipation device 2 are disposed closer to the -Z side than the lens barrel 37, the main circuit board 58 and the heat dissipation device 2 may be disposed closer to the +Z side than the lens barrel 37.

It should be noted that the image pickup apparatus, to which the present disclosure is applied, only needs to include a lens barrel and is not limited to a video camera.

According to the present disclosure, it is possible to improve the grip capability of the image pickup apparatus while suppressing the temperature rise inside the image pickup apparatus.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-079892, filed May 12, 2025, which is hereby incorporated by reference herein in its entirety.

What is claimed is:

1. An image pickup apparatus comprising:
a lens barrel;
a gripping portion for gripping a case of the image pickup apparatus;
a substrate on which a heat generating element is mounted, disposed on a side face of the lens barrel; and
a heat dissipation device configured to be disposed on the side face, have a flow path connecting an intake port provided in the case to an exhaust port provided in the case, and be thermally connected to the heat generating element, and
wherein the heat dissipation device and the gripping portion do not overlap with each other when viewed from a perpendicular direction of the gripping portion.

2. The image pickup apparatus according to claim 1, wherein
the heat dissipation device includes a plurality of air intake ports disposed on a main face, and an air exhaust port opening in a direction substantially perpendicular to a back face and the main face.

3. The image pickup apparatus according to claim 2, wherein
the heat dissipation device draws in air from the air intake ports by a high-speed vibration of a thin film enclosed within the heat dissipation device, and discharges the drawn-in air from the air exhaust port.

4. The image pickup apparatus according to claim 2, wherein
the air intake ports are in communication with the intake port, and
the air exhaust port is in communication with the exhaust port.

5. The image pickup apparatus according to claim 1, wherein
the gripping portion is disposed between two mounting portions for attaching a grip belt in an optical axis direction.

6. The image pickup apparatus according to claim 1, wherein
the exhaust port of the case is disposed closer to a subject side than the gripping portion in an optical axis direction.

7. The image pickup apparatus according to claim 1, wherein
the heat dissipation device and the case are connected via an elastic member.

8. The image pickup apparatus according to claim 1, wherein
the intake port of the case opens in a direction perpendicular to an optical axis direction.

9. The image pickup apparatus according to claim 1, wherein
a microphone is disposed on a face of the lens barrel that is different from the side face.

10. The image pickup apparatus according to claim 9, wherein
the face different from the side face is a top face of the lens barrel.

11. The image pickup apparatus according to claim 10, wherein
the exhaust port is open facing a subject side and facing downwards.

12. The image pickup apparatus according to claim 1, wherein
the gripping portion is disposed on the side face of the lens barrel, and
the heat dissipation device is disposed closer to a subject side than the gripping portion in an optical axis direction.

13. The image pickup apparatus according to claim 1, wherein
the substrate is equipped with a controller that controls the heat generating element.
